(19) United States
(12) Patent Application Publication
(10) Pub. No.: US 2023/0073160 A1
(43) Pub. Date: Mar. 9, 2023

(54) CLOCK GENERATING DEVICE, CONTROLLER, AND STORAGE DEVICE

(71) Applicant: SK hynix Inc., Icheon-si Gyeonggi-do (KR)

(72) Inventor: LAN FENG WANG, Zhubei City Hsinchu County (TW)

(73) Assignee: SK hynix Inc., Icheon-si Gyeonggi-do (KR)

(21) Appl. No.: 17/559,337

(22) Filed: Dec. 22, 2021

(30) Foreign Application Priority Data
Sep. 9, 2021 (TW) 110133524

(51) Int. Cl. G06F 13/16; G06F 13/38; H03L 7/16; H03L 7/24

(52) U.S. Cl. CPC G06F 13/1689; G06F 13/382; H03L 7/16; H03L 7/24

(57) ABSTRACT

A clock generating device, a controller and a storage device. The clock generating device comprises: a clock generator counter outputting a clock trigger signal according to a clock period of each reference number of a reference clock; a compensation counter module outputting a compensation signal, the compensation counter module comprises: a first compensation counter outputting a first compensation clock according to a clock period of each first compensation number of the reference clock, the first compensation number is greater than the reference number, the compensation signal includes the first compensation clock; and a clock generator, when the compensation signal is in a first state, the clock generator generates a target clock signal according to the clock trigger signal; when the compensation signal is in a second state, the clock generator cancels a corresponding pulse in the clock trigger signal according to the compensation signal to generate the target clock signal.

### CROSS-REFERENCE TO RELATED APPLICATION

The present application claims priority under 35 U.S.C. § 119(a) to Taiwanese Patent Application No. 110133524 filed on Sep. 9, 2021, in the Taiwan Intellectual Property Office, which is incorporated herein by reference in its entirety.

### BACKGROUND OF THE INVENTION

### 1. Field of the Invention

The present disclosure relates to a clock generator, and in particular to a clock generating device, a controller, and a storage device that are suitable to devices of an interconnection protocol.

### 2. Description of the Related Art

Because a quantity of data produced and processed in the current mobile devices (e.g., smartphones, tablets, multimedia devices, wearable devices and other computing devices) is continuously increasing, the chip to chip interconnection interface technology inside the mobile devices or affected by the mobile devices needs to further evolve to meet higher transmission speeds, low power operation, scalability, support for multitasking, easy adoption, and other goals.

To achieve the above goals, the Mobile Industry Processor Interface (MIPI) alliance has developed interconnection interface technologies that meet these goals, such as the MIPI M-PHY specification for the physical layer and the MIPI UniPro specification for the Unified Protocol (UniPro). On the other hand, the Joint Electronic Device Engineering Council (JEDEC) introduced the next generation of high-performance non-volatile memory standards, known as Universal Flash Storage (UFS), using the MIPI M-PHY specification and the unified protocol MIPI UniPro specification. This enables high-speed transmission at one billion bits per second and low-power operation, and provides the functionality and scalability required for high-end mobile systems, thus facilitating rapid adoption by the industry.

The UFS standard uses the UniPro specification to define multiple protocol layers in the link layer, which comprise the physical adapter layers, data link layers, network layers, and transport layers. Since the UniPro specification primarily defines the functionality of each protocol layer, and defines a conceptual service access point model to specify the interfaces of the services provided by each protocol layer for implementation, in compliance with the requirements of the UniPro specification, development engineers need to utilize individual technical solutions, possibly using hardware, firmware, or software for specific implementations.

In the UniPro specification, many threshold timers are defined and associated with specific operations. For example, (1) a link start timer is used to prevent errors in the link start sequence, which may send a timeout signal to stop the sequence when the link start sequence fails to be completed within a designated amount of time; (2) a hibernate exit timeout timer is used to prevent errors that occur during the hibernate exit sequence; and (3) a PHY Adapter Control Protocol (PACP) timeout timer is used to prevent errors that occur in power mode changing or during hibernate entry sequence.

In a system according to the UniPro specification, most threshold timers have a minimum resolution of 1 microsecond (10⁻⁶ s or 1 μs) of a clock signal. 1 microsecond of the clock tick can be generally generated by a reference clock. According to a traditional method, for example, if the reference clock is 19.2 MHz, a clock that is close to 1 μs for each 19 reference clocks passing through can be generated. The actual gap time of the generated clock is 989.583333 ns instead of 1000 ns. That is, the clock generated in the above example deviates approximately by 10.42 ns from the desired clock of 1 microsecond. With each clock passing through, the deviation time may continuously accumulate. Finally, the cumulative deviation time may be too large to manage, which can affect the operation of timers that rely on the generated clock.

### BRIEF SUMMARY OF THE INVENTION

The implementation provides a clock generating technology, suitable for linking a first device to a second device according to an interconnection protocol. By the technology, the accuracy of the timers used in the interconnection protocol can be enhanced.

According to the technology, the following various implementations are proposed, such as a clock generating device, controller, and storage device for an interconnection protocol.

The implementation provides a clock generating device, which comprises: a clock generator counter, a compensation counter module, and a clock generator. The clock generator counter is used for outputting a clock trigger signal according to a clock period of each reference number of a reference clock. The compensation counter module is used for outputting a compensation signal. The compensation counter module comprises: a first compensation counter for outputting a first compensation clock according to a clock period of each first compensation number of the reference clock, wherein the first compensation number is greater than the reference number, and the compensation signal includes the first compensation clock. The clock generator is used for receiving the clock trigger signal and the compensation signal to generate a target clock signal, wherein when the compensation signal is in a first state, the clock generator generates the target clock signal according to the clock trigger signal; when the compensation signal is in a second state, the clock generator cancels a corresponding pulse in the clock trigger signal according to the compensation signal to generate the target clock signal.

In some embodiments, the compensation counter module further comprises a second compensation counter for outputting a second compensation clock according to a clock period of each second compensation number of the reference clock, wherein the second compensation number is greater than the first compensation number, and the compensation signal further includes the second compensation clock.

In some embodiments, when either compensation clock of the first compensation clock and the second compensation clock included in the compensation signal is in a second state, the clock generator cancels a corresponding pulse in the clock trigger signal according to the compensation signal to generate the target clock signal.

In some embodiments, the compensation counter module further comprises a third compensation counter for outputting a third compensation clock according to a clock period of each third compensation number of the reference clock, wherein the third compensation number is greater than the second compensation number, and the compensation signal further includes the third compensation clock.

In some embodiments, when any one compensation clock of the first compensation clock, the second compensation clock, or the third compensation clock included in the compensation signal is in a second state, the clock generator cancels a corresponding pulse in the clock trigger signal according to the compensation signal to generate the target clock signal.

In some embodiments, the compensation counter module comprises: N compensation counters, the N compensation counters include the first compensation counter, and a kth compensation counter in the N compensation counters is used to output a kth compensation clock according to a clock period of a kth compensation number corresponding to the reference clock, wherein the kth compensation number is greater than a k−1th compensation number, the compensation signal further includes the kth compensation clock, N is an integer greater than or equal to 4, and k is an integer of any of 2 to N.

In some embodiments, when any one compensation clock of the first compensation clock to a Nth compensation clock included in the compensation signal is in a second state, the clock generator cancels the corresponding pulse in the clock trigger signal according to the compensation signal to generate the target clock signal.

The implementation provides a controller, which is suitable for linking a first device to a second device according to an interconnection protocol, the controller comprising: a processing unit; and a clock generating device. The clock generating device is coupled to the processing unit and includes: a clock generation counter, a compensation counter module, and a clock generator. The clock generation counter is used for outputting a clock trigger signal according to a clock period of each reference number of a reference clock. The compensation counter module is used for outputting a compensation signal. The compensation counter module includes a first compensation counter for outputting a first compensation clock according to a clock period of each first compensation number of the reference clock, wherein the first compensation number is greater than the reference number, and the compensation signal includes the first compensation clock. The clock generator is used for receiving the clock trigger signal and the compensation signal to generate a target clock signal, wherein the clock generator generates the target clock signal according to the clock trigger signal when the compensation signal is in a first state; when the compensation signal is in a second state, the clock generator cancels a corresponding pulse in the clock trigger signal according to the compensation signal to generate the target clock signal; when the processing unit activates the clock generating device, the processing unit transmits a value of the reference number to the clock generator counter and at least transmits a value of the first compensation number to the first compensation counter.

In some embodiments of the controller, the compensation counter module comprises: N compensation counters, the N compensation counters include the first compensation counter, and a kth compensation counter in the N compensation counters is used to output a kth compensation clock according to a clock period of a kth compensation number corresponding to the reference clock, wherein the kth compensation number is greater than a k−1th compensation number, the compensation signal further includes the kth compensation clock, N is an integer greater than or equal to 2, and k is an integer of any of 2 to N.

In some embodiments of the controller, when any one compensation clock of the first compensation clock to a Nth compensation clock included in the compensation signal is in a second state, the clock generator cancels the corresponding pulse in the clock trigger signal according to the compensation signal to generate the target clock signal.

The implementation provides a storage device, which is capable of linking to a host according to an interconnection protocol, the storage device including: an interface circuit and a device controller. The interface circuit is used for implementing a physical layer of the interconnection protocol to link with the host. The device controller is used for coupling to the interface circuit and a storage module, wherein the device controller includes: a processing unit; and a clock generating device of any one of the above embodiments. When the processing unit activates the clock generating device, the processing unit transmits a value of the reference number to the clock generator counter and at least transmits a value of the first compensation number to the first compensation counter.

In some embodiments, the interconnection protocol is a Universal Flash Storage (UFS) standard.

### BRIEF DESCRIPTION OF THE DRAWINGS

FIG. 1 is a schematic block diagram of a clock generating device according to an implementation of the present disclosure.

FIG. 2 is a schematic block diagram of a clock generating device according to an embodiment.

FIG. 3A is a schematic block diagram of a clock generating device according to an implementation of the present disclosure.

FIG. 3B is a schematic waveform graph of a clock generating device according to an implementation of the present disclosure.

FIG. 4 is a schematic block diagram of a storage system according to an implementation of the present disclosure.

### DETAILED DESCRIPTION OF THE INVETION

To facilitate understanding of the object, characteristics and effects of this present disclosure, embodiments together with the attached drawings for the detailed description of the present disclosure are provided.

The following implementation provides a clock generating technology that enhances the accuracy of the timers used in the interconnection protocol. The circuit architecture generated by the following clock provides a flexible way to improve the accuracy of the generated target clock signal by reducing the cumulative deviation time, suitable for use in systems according to the UniPro specification.

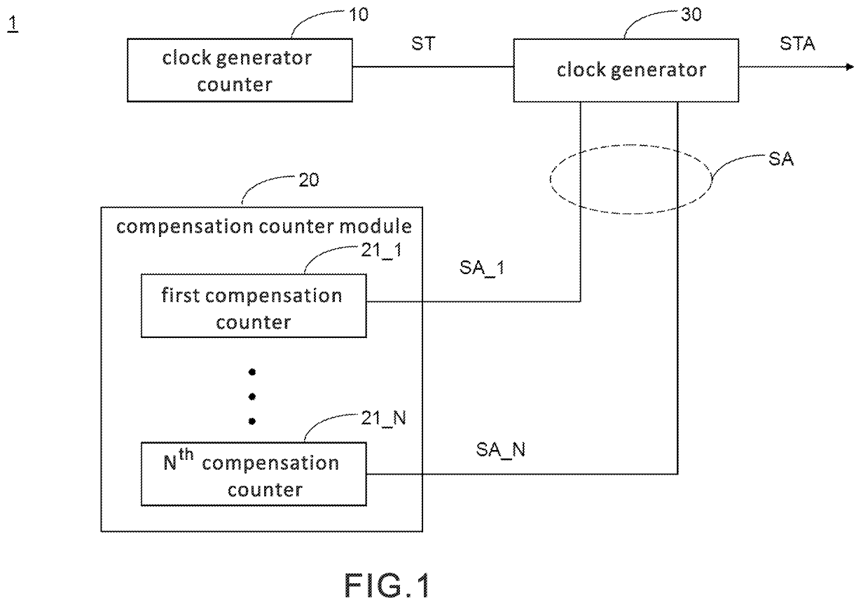

Referring to FIG. 1, FIG. 1 is a schematic block diagram of a clock generating device according to an implementation of the present disclosure. As shown in FIG. 1, the clock generating device 1 comprises: a clock generator counter 10, a compensation counter module 20, and a clock generator 30. The clock generating device 1 is used to generate a target clock signal STA according to a reference clock, for example, in a system according to the UniPro specification, most threshold timers have a minimum resolution of 1 microsecond (10⁻⁶ s or 1 μs) of a clock signal. Indeed, the implementation of the present disclosure is not limited by the examples.

The clock generator counter 10 is used for outputting a clock trigger signal ST according to a clock period of each reference number of the reference clock. The reference clock may be a clock built into the clock generator counter 10 or an external clock; the reference clock, for example, is a clock that can be generated by a commercially available vibration circuit or counter circuit, such as one in a frequency of 19.2 MHz, 26 MHz, 38.4 MHz, 52 MHz, or others. The clock generator counters may be implemented by a variety of counter circuits or programmable counters.

The compensation counter module 20 is used for outputting a compensation signal SA. The compensation counter module 20 comprises at least one or more compensation counters (i.e., N=1 or N>1). For example, a first compensation counter 21_1 is used to output a first compensation clock SA_1 according to a clock period of each first compensation number of the reference clock, wherein the first compensation number is greater than the reference number, and the compensation signal SA comprises the first compensation clock SA_1. In some embodiments, if the compensation counter module 20 comprises N compensation counters, the N compensation counters include the first compensation counter 21_1, and a kth compensation counter in the N compensation counters is used to output a kth compensation clock according to a clock period of a kth compensation number corresponding to the reference clock, wherein the kth compensation number is greater than a k-lth compensation number, the compensation signal SA further includes the kth compensation clock, N is an integer greater than or equal to 2, and k is an integer of any of 2 to N. Compensation counters can be implemented by a variety of counter circuits or programmable counters. In addition, for example, the compensation numbers of the compensation counter may depend on the accuracy required for the target clock signal STA.

The clock generator 30 is used for receiving the clock trigger signal ST and the compensation signal SA to generate a target clock signal STA, wherein when the compensation signal SA is in a first state (e.g., low level, indicating no compensation), the clock generator 30 generates the target clock signal STA according to the clock trigger signal ST; when the compensation signal SA is in a second state (e.g., high level, indicating that the compensation is needed), the clock generator 30 cancels a corresponding pulse in the clock trigger signal ST according to the compensation signal SA to generate the target clock signal STA.

In some embodiments, the compensation counter module 20 comprises N compensation counters, and when any one compensation clock of the first compensation clock to a Nth compensation clock included in the compensation signal SA is in a second state, the clock generator 30 can be configured to cancel the corresponding pulse in the clock trigger signal ST according to the compensation signal SA to generate the target clock signal STA.

For example, if the reference clock is 19.2 MHz, the clock generator counter 10 generates a clock trigger signal ST that is close to the desired clock (e.g., 1 μs) for each 19 reference clocks (in this example, reference number is 19) passing through. The actual gap time (gap time) or period for each of the two pulses of the clock trigger signal ST is 989.583333 ns instead of 1000 ns. That is, the clock generated in this example deviates approximately by 10.42 ns from the desired clock of 1 microsecond. With each clock passing through, the deviation time may continuously accumulate.

In order to overcome the cumulative deviation that is caused by the clock trigger signal ST generated by the clock generator counter 10 and to tolerate the inaccuracy of the reference clock, the present invention discloses a circuit architecture to obtain a target clock signal STA with a higher accuracy based on the additional counter by the embodiment of FIG. 1. According to the architecture, when implemented, the target clock signal STA can be generated according to the clock trigger signal ST, the clock trigger signal ST can choose the appropriate reference clock and reference number to make the gap between the pulses of the clock small, but it is closest to the ideal desired clock (e.g., 1 μs). For the convenience of discussion, the gap time or period of the clock trigger signal ST generated by the clock generator counter 10 is named as Tg. The maximum deviation time between the clock trigger signal ST and the ideal desired clock (e.g., 1 μs) is less than 1 reference clock period time, named Tr.

With time passing through, the deviation time is accumulated in each clock Tr. When the cumulative deviation time of the compensation counter module 20 is greater than Tg, the output compensation signal SA is changed from the first state to the second state, and one pulse that has been generated is canceled by the clock generator 30 to compensate the cumulative deviation.

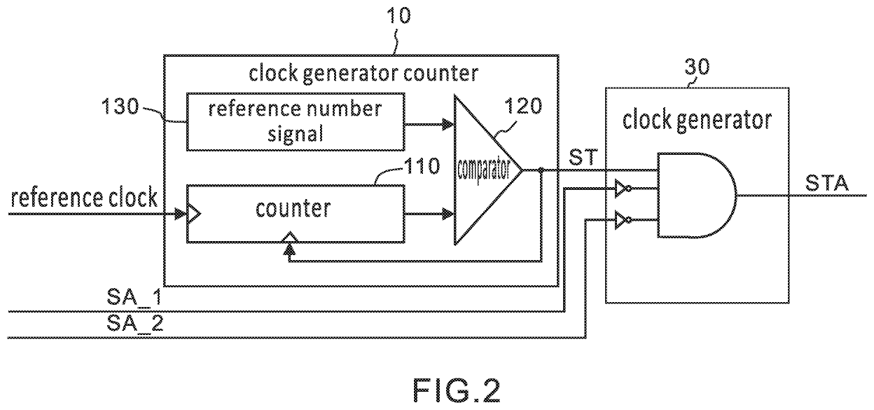

In some embodiments, the clock generator 30 can compensate the deviation of the clock trigger signal ST by logical operation, the clock trigger signal ST after compensating can be output as a target clock signal STA. For example, in cases where the compensation signal comprises only one compensation clock (as expressed in SA_1), the clock generator 30 can be implemented by using the logical operation of STA=ST·SA_1′. In cases where the compensation signal comprises multiple compensation clocks (as expressed in SA_1, SA_2), the clock generator 30 can be implemented by using the logical operations of STA=ST·(SA_1+SA_2)′=ST·SA_1′·SA_2′. Referring to an example in FIG. 2, logic gate of logic sum and logic negation is used to implement the clock generator 30 with the logical operation of STA=ST·SA_1′·SA_2′. Indeed, the clock generator 30 can be implemented in the form of any other suitable logic circuit, such as STA=ST·(SA_1+SA_2)′ or others, thus not limited to the above examples. As the number of compensation clock is more than 3, the above embodiments are for reference, and so on.

In some embodiments, in order to overcome the cumulative deviation time, the compensation counter module 20 may comprise N compensation counters, equivalent to the logic of an N-level correction (or compensation) to implement the target accuracy of the ideal desired clock (e.g. 1 μs) over a specific period of time.

In some embodiments, when the clock generating device is to be activated, the value of the reference number can be transmitted to the clock generator counter 10 by a processing unit (e.g., in the form of firmware) and at least the value of the first compensation number can be transmitted to the first compensation counter 21_1. If the compensation counter module 20 comprises N compensation counters, the processing unit (e.g., in the form of firmware) can respectively transmit N values corresponding to the compensation counters 21_1 to 21_N that is used to generate the corresponding compensation clock of the first compensation number to the Nth compensation number to the compensation counters 21_1 to 21_N, for example, in registers of the compensation counters. Thus, the clock generator counter 10 and the compensation counters 21_1 to 21_N will operate.

For example, referring to FIG. 2, an embodiment of the clock generator counter 10 is illustrated. In the embodiment of FIG. 2, the clock generator counter 10, for example, may comprise a counter 110 and a comparator 120. The counter 110, for example, is an incremental counter, the counter 110 receives a reference clock. The comparator 120 receives and compares an output signal of the counter 110 and a reference number signal 130 representing a reference number. When the comparator 120 determines that the output signal meets the reference number, a pulse of the clock trigger signal ST is output, thus implementing that the clock generator counter 10 outputs the clock trigger signal ST according to the clock period of each reference number of the reference clock. In addition, the pulse of the clock trigger signal ST can also be used as a reset signal to reset the counter 110.

For example, the clock generator counter 10 shown in FIG. 2 can also be configured to receive the reference number signal 130 transmitted by the processing unit (e.g., in the form of firmware) in the previous embodiment. In some embodiments, a memory unit (e.g., a register or any suitable memory element) can be set to store the reference number signal 130 in or outside the clock generator counter 10, and the memory unit can be used to provide reference numbers to the comparator 120. In another embodiment, the clock generator counter 10 can be configured to have a reference number signal 130 as a value without relying on external equipment to provide the reference numbers.

For example, the compensation counters (e.g., the first compensation counter 21_1 to the Nth compensation counter 21_N) in the compensation counter module 20 can also be implemented according to any embodiment or a combination thereof of the clock generator counter 10. For example, a compensation counter (such as the first compensation counter 21_1 or the second compensation counter 21_2) comprises a counter and a comparator; the comparator receives and compares an output signal of the counter and a compensation number signal representing a compensation number. When the comparator determines that the output signal meets the compensation number, a pulse of the compensation clock (e.g., SA_1 or SA_2) is output, thus implementing that the compensation counter outputs a compensation clock (e.g., SA_1 or SA_2) according to the clock period of each compensation number of the reference clock. Indeed, the clock generator counter 10 or the compensation counter module 20 can be implemented with any other suitable counter and/or logic circuit, thus not limited to the above example.

By the mechanism used in the circuit architecture of FIG. 1, the limitation of clock accuracy of the traditional timer circuit can be broken through, and the requirement of higher accuracy of the reference clock period can be implemented. The circuit architecture of FIG. 1 is used to implement timers in an interconnection protocol, for example, to generate precise clock ticks of microseconds (e.g., 1 μs, 2 μs and above, or less than 1 μs). By increasing or decreasing the number (or level) of compensation counters in the compensation counter module 20, the target deviation can be flexibly implemented with the appropriate hardware resources over a specific period of time.

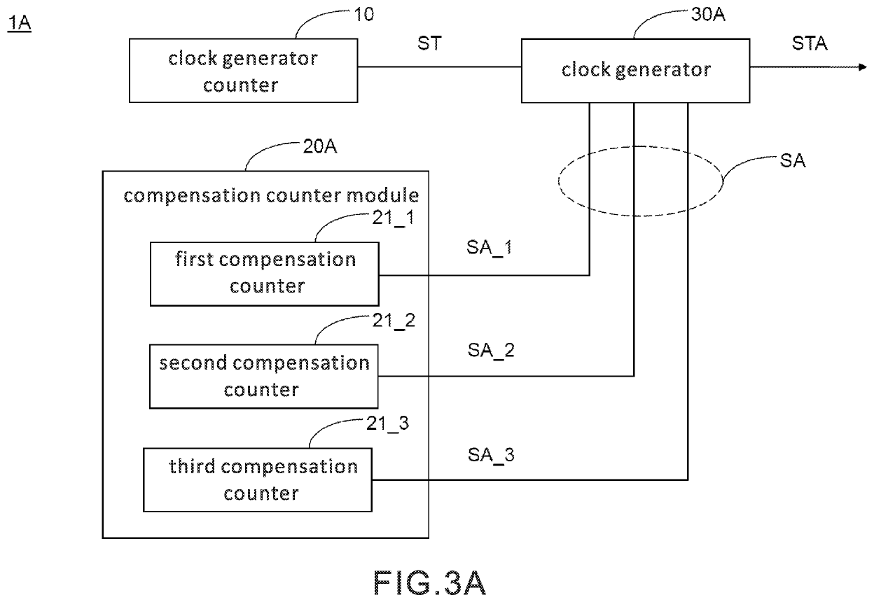

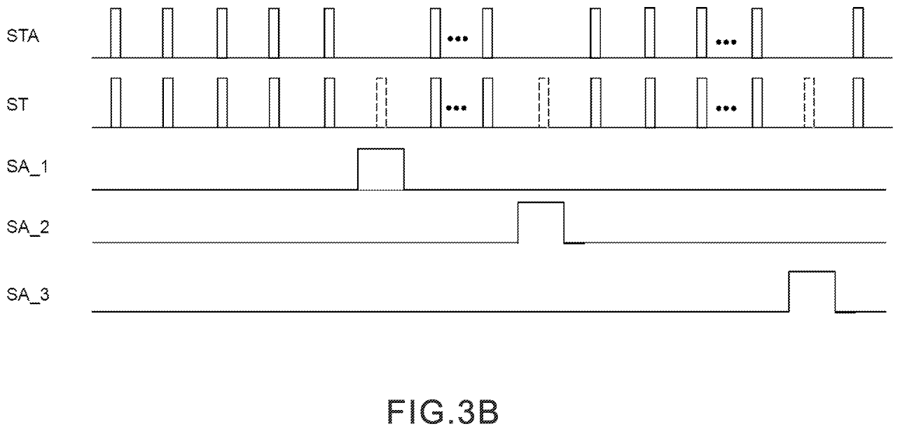

The following takes that the compensation counter module has three compensation counters for an example, illustrating the circuit architecture according to FIG. 1. Referring to FIG. 3A, a schematic block diagram of a clock generating device according to an implementation of the present disclosure is illustrated.

As shown in FIG. 3A, the clock generating device 1A comprises: a clock generator counter 10, a compensation counter module 20A, a clock generator 30A. In FIG. 3A, the clock generator counter 10 is the same as that in FIG. 1, so detailed description is not repeated.

As shown in FIG. 3A, the compensation counter module 20A is used for outputting a compensation signal SA. The compensation counter module 20 comprises a first compensation counter 21_1, which is used to output a first compensation clock SA_1 according to a clock period of each first compensation number of the reference clock, wherein the first compensation number is greater than the reference number, and the compensation signal SA comprises the first compensation clock SA_1. The compensation counter module 20A further comprises a second compensation counter 21_2, which is used to output a second compensation clock SA_1 according to the clock period of each second compensation number of the reference clock, wherein the second compensation number is greater than the first compensation number, and the compensation signal SA further comprises the second compensation clock SA_2. The compensation counter module 20A further comprises a third compensation counter 21_3, which is used to output a third compensation clock SA_3 according to the clock period of each third compensation number of the reference clock, wherein the third compensation number is greater than the second compensation number, and the compensation signal SA further comprises the third compensation clock SA_3.

The clock generator 30A is used for receiving the clock trigger signal ST and the compensation signal SA to generate a target clock signal STA, wherein when the compensation signal SA is in a first state (e.g., low level, indicating no compensation), the clock generator 30A generates the target clock signal STA according to the clock trigger signal ST; when the compensation signal SA is in a second state (e.g., high level, indicating that the compensation is needed), the clock generator 30A cancels a corresponding pulse in the clock trigger signal ST according to the compensation signal SA to generate the target clock signal STA.

In some embodiments, when either compensation clock of the first compensation clock SA_1 or the second compensation clock SA_2 included in the compensation signal SA is in a second state, the clock generator 30A cancels a corresponding pulse in the clock trigger signal ST according to the compensation signal SA to generate the target clock signal STA.

In some embodiments, when any one compensation clock of the first compensation clock or the second compensation clock or the third compensation clock included in the compensation signal SA is in a second state, the clock generator 30A cancels a corresponding pulse in the clock trigger signal ST according to the compensation signal SA to generate the target clock signal STA.

Referring to FIG. 3B, the upper pulse indicates the clock trigger signal ST, wherein when any one compensation clock in the compensation signal SA is in the second state (e.g., high level or logic 1), the clock generator 30A cancels the corresponding pulse in the clock trigger signal ST to generate the target clock signal STA. In FIG. 3B, the canceled pulse in the clock trigger signal ST is indicated by a dashed line, while the position of the target clock signal STA corresponding to the canceled pulse is in the first state (e.g., low level or logic 0).

The above mentioned that by increasing or decreasing the number (or referred to as level) of compensation counters in the compensation counter module 20, the target deviation can be flexibly implemented with the appropriate hardware resources over a specific period of time. Therefore, the following embodiments are provided to illustrate details, according to the circuit architecture of FIG. 1, multiple (or referred to as level) compensation counters are implemented to meet the needs of different accuracy.

In the following embodiments, assume that: (1) the period time of the physical reference clock is 52.08 ns (reference clock frequency is 19.2 MHz); (2) the goal is to generate a clock tick of 1 microsecond; (3) the goal is to make a deviation time less than 1 ppb within 24 hours. In addition, using the architecture of the clock generating device 1 in FIG. 1, the parameters of multiple (or level) compensation counters can be calculated by following steps 1 to 6.

Step 1: calculating the value of the reference number of the clock generator counter 10. The goal is to generate a clock tick of 1 microsecond. Since 1000/52.08=19.20122887864823, taking its quotient, the reference number is 19. Thus, the physical period of the clock trigger signal ST generated by the clock generator counter 10 is 19*52.08=989.52 ns. The deviation time from the ideal 1 us for each generated clock is 1000-989.52=10.48 ns.

Step 2: calculating the value of the first compensation number of the first compensation counter 21_1. The deviation time of the clock generator counter 10 accumulates over time. Therefore, it is calculated to find how many clock pulses are generated so that the cumulative deviation time will exceed the clock trigger signal ST by one pulse: 989.52/10.48=94.4198. It indicates that the cumulative deviation time exceeds the clock trigger signal ST by the time of one pulse after 95 pulses are generated. The deviation can be compensated by canceling the pulse generated by the 95th of the clock trigger signal ST, and the first compensation number is 19. After the action of the cancellation, when the next pulse of the target clock signal STA is asserted, i.e., when the actual 95th pulse of the target clock signal STA outputted, the corresponding actual time interval is: 989.52*95+989.52=94993.92 ns. After 95 pulses are generated, the deviation time using the first compensation counter 21_1 for compensation (or first-level compensation) is: 95000-94993.92=6.08 ns.

Step 3: calculating the value of the second compensation number of the second compensation counter 21_2. The deviation time of 6.08 ns for the first-level compensation will accumulate. The number of rounds that the cumulative deviation time exceeds one actual generated pulse time is calculated (95 pulses per round): 989.52/6.08=162.75, i.e., 95*163 pulses are generated each, one pulse needs to be canceled to compensate the cumulative deviation time introduced by the deviation time (e.g., 6.08 ns) of the first-level compensation, so the second compensation number is 95*163. The actual time interval for the 95*163 pulses is: 94993.92*163+989.52=15484995.48 ns. Then, after 95*163 pulses are generated, the deviation time using the second compensation counter 21_2 for compensation (or second-level compensation) is: 15484500-15484995.48=4.52 ns.

Step 4: calculating the value of the third compensation number of the third compensation counter 21_3. Similarly, the deviation time of 4.52 ns for the second-level compensation will accumulate. The number of rounds that the cumulative deviation time of the second-level compensation exceeds one actual generated pulse time is calculated (95*163 pulses per round): 989.52/4.52=218.920. That is 95*163*219 pulses are generated each, one pulse needs to be canceled to compensate the deviation time introduced by the deviation time (e.g., 4.52 ns) of the second-level compensation, so the third compensation number is 95*163*219. The actual time interval for the 95*163*219 pulses is: 15484995.48*219+989.52=3391214999.64 ns. After 95*163*219 pulses are generated, the deviation time using the third compensation counter 21_3 for compensation (or third-level compensation) is: 3391215000-3391214999.64=0.36 ns. 3391215000 ns is about 3.391 seconds.

Step 5: calculating the value of the fourth compensation number of the fourth compensation counter 21_4. The deviation time of 0.36 ns for the third-level compensation will accumulate. The number of rounds that the cumulative deviation time of the third-level compensation exceeds one actual generated pulse time is calculated: 989.52/0.36=2748.66667. Then, 95*163*219*2749 pulses are generated each, one pulse needs to be canceled to compensate the deviation time introduced by the deviation time (e.g., 0.36 ns) of the third-level compensation, so the fourth compensation number is 95*163*219*2749. The actual time interval for the 95*163*219*2749 pulses is: 3391214999.64*2749+989.52=9322450034999.88 ns. After 95*163*219*2749 pulses are generated, the deviation time using the fourth compensation counter 21_4 for compensation (or fourth-level compensation) is: 9322450035000-9322450034999.88=0.12 ns. 9322450035000 ns is about 9322.450 seconds (2.589 hours), while the deviation time is 0.12 ns.

Step 6: calculating the value of the fifth compensation number of the fifth compensation counter 21_5. The deviation time of 0.12 ns for the fourth-level compensation will accumulate. The number of rounds that the cumulative deviation time of the fourth-level compensation exceeds one actual generated pulse time is calculated: 989.52/0.12=8246. Then, 95*163*219*2749*8246 pulses are generated each, one pulse needs to be canceled to compensate the deviation time introduced by the deviation time (e.g., 0.12 ns) of the fourth-level compensation, so the fifth compensation number is 95*163*219*2749*8246. The actual time interval for the 95*163*219*2749*8246 pulses is: 9322450034999.88*8246+989.52=76872922988610000 ns. After 95*163*219*2749*8246 pulses are generated, the deviation time using the fifth compensation counter 21_5 for compensation (or fifth-level compensation) is: 76872922988610000-76872922988610000=0 ns. 76872922988610000 ns is about 76872922.98 seconds (21353.589 hours), while the deviation time is 0 ns.

As can be seen from steps 1 to 6 of the above embodiments, by increasing or decreasing the number (or level) of compensation counters in the compensation counter module 20, and by determining the parameters of each compensation counter, the target deviation can be flexibly implemented with the appropriate hardware resources over a specific period of time. For example, the clock generating device can be implemented according to the design of accuracy requirements, taking one kind of level in multiple levels compensation, and according to the architecture of FIG. 1. Further, the method for calculating parameters involved in the above steps 1 to 6 can also be performed automatically using a computing device or processing unit.

In implementation, the clock generating device can be implemented by the processing unit (e.g., in the form of firmware) or programmability. The following is illustrated by using an implementation of a circuit architecture of a storage system.

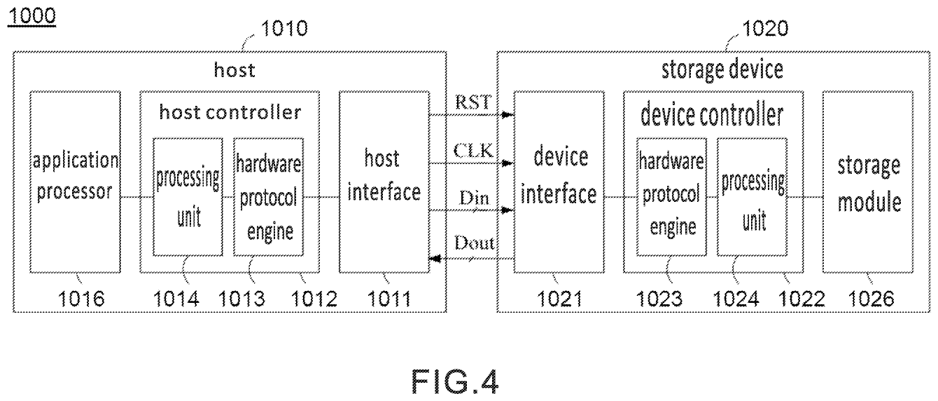

For the convenience of understanding and illustration, the following further provides an implementation of circuit architecture according to the technology, the circuit architecture is flexible enough and can be efficiently configured to meet the specific needs of different product manufacturers, to adapt to the design of various manufacturers and contribute to product development. As shown in FIG. 4, when the circuit architecture is applied to the storage system 1000, the controller (e.g., host controller 1012) of the host 1010 of the storage system 1000 or the controller (e.g., device controller 1022) of the storage device 1020 of the storage system 1001 can be respectively implemented as a circuit architecture including a hardware protocol engine and a processing unit, wherein the processing unit of the controller is optional. The method of the technology for data processing of an interconnection protocol will also be disclosed in FIG. 3A.

Referring to FIG. 4, FIG. 4 is a schematic block diagram of a storage system according to an implementation of the present disclosure. As shown in FIG. 4, the storage system 1000 comprises a host 1010 and a storage device 1020. The host 1010 and storage device 1020 communicate through an interconnection protocol, thus allowing the host 1010 access data to the storage device 1020. The interconnection protocol, for example, is a Universal Flash Storage (UFS) standard. The host 1010 is a computing device, for example, a smartphone, tablet, or multimedia device. The storage device 1020, for example, is a storage device inside or outside of the computing device, such as a storage device based on non-volatile memory. The storage device 1020 can write data under the control of the host 1010 or provide written data to the host 1010. The storage device 1020 may be implemented as a solid-state storage device (SSD), multimedia card (MMC), embedded MMC (eMMC), secure digital (SD) card, or Universal Flash Storage (UFS) device, however, the implementation of the present disclosure is not limited to the above examples.

The host 1010 comprises a host interface 1011, a host controller 1012, and an application processor 1016.

The host interface 1011 is configured to implement a physical layer of the interconnection protocol so as to link to the storage device 1020. For example, the host interface 1011 is configured to implement the physical (M-PHY) layer of the UFS standard.

The host controller 1012 is coupled between the host interface 1011 and the application processor 1016. When the application processor 1016 needs to access data of the storage device 1020, it issues a corresponding access action instruction to the host controller 1012, and communicates with the storage device 1020 through the interconnection protocol, so as to achieve accessing data of the storage device 1020.

The host controller 1012 comprises a hardware protocol engine 1013 and a processing unit 1014, wherein the processing unit 1014 is optional.

The hardware protocol engine 1013 is configured to implement a link layer for the interconnection protocol. Taking the interconnection protocol as a UFS standard for example, the link layer is a Unified Protocol (UniPro) layer. The hardware protocol engine 1013 communicates and conducts information conversion with the host interface 1011 and the processing unit 1014 according to the specification of the link layer.

The processing unit 1014 is coupled to the hardware protocol engine 1013, and configured to communicate with the application processor 1016. The processing unit 1014 may execute one or more firmware elements. For example, access action instructions that are issued by the operating system, driver, or application performed by the application processor 1016 are converted to an instruction format of the link layer that conforms to the interconnection protocol through the firmware performed by the processing unit 1014, and then sent to the hardware protocol engine 1013 for processing according to the specification of the link layer. The firmware, for example, is stored in an internal memory in the processing unit 1014, or stored in an internal memory in the host controller 1012, wherein the internal memory may comprise volatile memory and non-volatile memory.

The storage device 1020 comprises a device interface 1021, a device controller 1022, and a storage module 1026.

The device interface 1021 is configured to implement a physical layer of the interconnection protocol so as to link to the host 1010. For example, the host interface 1021 is configured to implement the physical (M-PHY) layer of the UFS standard.

The device controller 1022 is coupled between the device interface 1021 and the storage module 1026. The device controller 1022 may control a write operation, read operation, or erase operation of the storage module 1026. The device controller 1022 may exchange data with the storage module 1026 through an address bus or data bus. The storage module 1026, for example, is a memory chip comprising one or more non-volatile memory elements.

The device controller 1022 comprises a hardware protocol engine 1023 and a processing unit 1024, wherein the processing unit 1024 is optional.

The hardware protocol engine 1023 is configured to implement a link layer for the interconnection protocol. Taking the interconnection protocol as a UFS standard for example, the link layer is a UniPro layer. The hardware protocol engine 1013 communicates and conducts information conversion with the device interface 1021 and the processing unit 1024 according to the specification of the link layer.

The processing unit 1024 is coupled to the hardware protocol engine 1023, configured to communicate with the host 1010 through the device interface 1021. The processing unit 1024 may perform one or more firmware elements. For example, the processing unit 1024 executes one or more firmware to control or indicate the write operation, read operation, or erase operation of the storage module 1026, processes messages from the hardware protocol engine 1023, or sends messages to the hardware protocol engine 1023. The firmware, for example, is stored in an internal memory in the processing unit 1024, or stored in an internal memory in the device controller 1022, or stored in a specific storage area of the storage module 1026, wherein the internal memory may comprise volatile memory and non-volatile memory.

As shown in FIG. 4, the host interface 1011 may be coupled to the device interface 1021 through the data lines Din and Dout used to send/receive data, the reset line RST used to send hardware reset signals, and the clock line CLK used to send data. The data lines Din and Dout may be implemented as multiple pairs, and one pair of data lines Din or Dout can be called a lane. The host interface 1011 may communicate with the device interface 1021 by using at least one interface protocol, such as Mobile Industry Processor Interface (MIPI), Universal Flash Storage (UFS), Small Computer System Interface (SCSI), or Serial Attached SCSI (SAS), but the implementation of the disclosure is not limited to the above examples.

Controllers as shown in FIG. 4 (e.g., host controller 12 or device controller 22) may be respectively implemented as circuit architectures that comprise a hardware protocol engine and a processing unit.

In some implementations according to FIG. 4, a controller (as host controller 1012 or device controller 1022 of FIG. 4) is provided, which is suitable for linking a first device to a second device according to an interconnection protocol (e.g., UFS standard), the controller comprising: a processing unit (as 1014 or 1024 of FIG. 4); and a clock generating device (as 1 of FIG. 1). The clock generating device 1 is coupled to the processing unit. When the processing unit activates the clock generating device 1, the processing unit transmits a value of the reference number to the clock generator counter 10 and at least transmits a value of the first compensation number to the first compensation counter.

In some embodiments of the controller, the compensation counter module 20 comprises: N compensation counters, the N compensation counters include the first compensation counter, and a kth compensation counter in the N compensation counters is used to output a kth compensation clock according to a clock period of a kth compensation number corresponding to the reference clock, wherein the kth compensation number is greater than a k-lth compensation number, the compensation signal SA further includes the kth compensation clock, N is an integer greater than or equal to 2, and k is an integer of any of 2 to N.

In some embodiments of the controller, when any one compensation clock of the first compensation clock to a Nth compensation clock included in the compensation signal SA is in a second state, the clock generator 30 can be configured to cancel the corresponding pulse in the clock trigger signal ST according to the compensation signal SA to generate the target clock signal STA.

In an implementation according to FIG. 4, a storage device (as 1020 of FIG. 4) is provided, which is capable of linking to a host (as 1010 of FIG. 4) according to an interconnection protocol (e.g., UFS standard), the storage device including: an interface circuit (as 1021 of FIG. 4) and a device controller (as 1022 of FIG. 4). The interface circuit is used for implementing a physical layer of the interconnection protocol to link with the host. The device controller is used for coupling to the interface circuit and a storage module, wherein the device controller includes: a processing unit (as 1024 of FIG. 4) and a clock generating device 1 of any one of the above embodiments. when the processing unit activates the clock generating device 1, the processing unit transmits a value of the reference number to the clock generator counter 10 and at least transmits a value of the first compensation number to the first compensation counter.

For example, the clock generating device (as 1 of FIG. 1) can be set or implemented in a controller (e.g., host controller 1012 or device controller 1022) in FIG. 4. For example, the clock generating device (as 1 of FIG. 1) can be implemented in the hardware protocol engine 1013 or the hardware protocol engine 1023 of FIG. 4. For example, the clock generating device (as 1 of FIG. 1) can further be set or implemented in a controller (e.g., host controller 1012 or device controller 1022) in FIG. 4. and outside the hardware protocol engine of FIG. 4 (e.g., 1013 or 1023). For example, the clock generating device (as 1 of FIG. 1) can further be set or implemented in a processing unit (e.g., 1014 or 1024 of FIG. 4) of a controller (e.g., host controller 1012 or device controller 1022) in FIG. 4.

In addition, the above embodiments disclose that the clock generating device can be implemented according to the design of accuracy requirements, taking one kind of level in multiple levels compensation, and according to the architecture of FIG. 1, and can be applied to the above embodiments based on FIG. 4. Further, the method for calculating parameters of multiple levels compensation of the above embodiment (as steps 1 to 6) can also be performed automatically using a processing unit (e.g., 1014 or 1024 of FIG. 4) for generating (e.g., reference number, at least one of multiple compensation numbers). In other embodiments, the processing unit (e.g., 1014 or 1024 of FIG. 4) can also store parameters (e.g., reference number, at least one of multiple correction numbers) without conducting calculation. Indeed, the implementation of the present disclosure is not limited by the above examples; various embodiments can be combined under appropriate circumstances.

In addition, in the above embodiments for the host and the storage device, the hardware protocol engine in the host controller or device controller can be designed based on technologies of any other design method using a hardware description language (HDL) such as the Verilog language or digital circuit familiar to those skilled in the art, and can be implemented based on the use of field programmable gate array (FPGA), or one or more circuits such as application specific integrated circuit (ASIC) or complex programmable logic device (CPLD), can also be implemented by using proprietary circuits or modules. The host controller or device controller (or a processing unit or hardware protocol engine thereof) can also be implemented based on a microcontroller, processor, or digital signal processor.

While the present disclosure has been described by means of specific embodiments, numerous modifications and variations could be made thereto by those skilled in the art without departing from the scope and spirit of the present disclosure set forth in the claims.

What is claimed is:

1. A clock generating device, comprising:
a clock generator counter for outputting a clock trigger signal according to a clock period of each reference number of a reference clock;
a compensation counter module for outputting a compensation signal, the compensation counter module comprising:
a first compensation counter for outputting a first compensation clock according to a clock period of each first reference number of the reference clock, wherein a first compensation number is greater than a reference number, and the compensation signal includes the first compensation clock; and
a clock generator for receiving the clock trigger signal and the compensation signal to generate a target clock signal, where
when the compensation signal is in a first state, the clock generator generates a target clock signal according to the clock trigger signal;
when the compensation signal is in a second state, the clock generator cancels a corresponding pulse in the clock trigger signal according to the compensation signal to generate the target clock signal.

2. The clock generating device according to claim 1, wherein the compensation counter module further comprises:
a second compensation counter for outputting a second compensation clock according to a clock period of each second compensation number of the reference clock, wherein the second compensation number is greater than the first compensation number, and the compensation signal includes the second compensation clock.

3. The clock generating device according to claim 2, wherein the clock generator uses the first compensation clock and the second compensation clock included in the compensation signal, when either compensation clock is in the second state, the corresponding pulse in the clock trigger signal is canceled according to the compensation signal to generate the target clock signal.

4. The clock generating device according to claim 2, wherein the compensation counter module further comprises:
a third compensation counter for outputting a third compensation clock according to a clock period of each third compensation number of the reference clock, wherein the third compensation number is greater than the second compensation number, and the compensation signal includes the third compensation clock.

5. The clock generating device according to claim 4, wherein the clock generator uses the first compensation clock, the second compensation clock, and the third compensation clock that are included in the compensation signal, when any compensation clock is in the second state, the corresponding pulse in the clock trigger signal is canceled according to the compensation signal to generate the target clock signal.

6. The clock generating device according to claim 1, wherein the compensation counter module comprises:
N compensation counters, the N compensation counters include the first compensation counter, and a kth compensation counter in the N compensation counters is used to calculate a clock cycle of a kth compensation number corresponding to the reference clock to output a kth compensation clock, where the kth compensation number is greater than a k−1th compensation number, the compensation signal further includes the kth compensation clock, N is an integer greater than or equal to 4, and k is an integer of any of 2 to N.

7. The clock generating device according to claim 6, wherein the clock generator uses the first compensation clock to a Nth compensation clock included in the compensation signal, when any compensation clock is in the second state, the corresponding pulse in the clock trigger signal is canceled according to the compensation signal to generate the target clock signal.

8. The clock generating device according to claim 1, wherein interface protocol is a Universal Flash Storage (UFS) standard.

9. A controller suitable for linking a first device to a second device according to an interface protocol, the controller comprising:
a processing unit; and
a clock generating device, which is coupled to the processing unit and includes:
a clock generation counter for outputting a clock trigger signal according to a clock period of each reference number of a reference clock;
a compensation counter module for outputting a compensation signal, the compensation counter module including:
a first compensation counter for outputting a first compensation clock according to a clock period of each first compensation number of the reference clock, wherein the first compensation number is greater than the reference number, and the compensation signal includes the first compensation number and the first compensation clock; and
a clock generator for receiving the clock trigger signal and the compensation signal to generate a target clock signal, where
the clock generator generates the target clock signal according to the clock trigger signal when the compensation signal is in a first state;
when the compensation signal is in a second state, the clock generator cancels a corresponding pulse in the clock trigger signal according to the compensation signal to generate the target clock signal;
when the processing unit activates the clock generating device, the processing unit transmits a value of the reference number to the clock generator counter and at least transmits a value of the first compensation number to the first compensation counter.

10. The controller according to claim 9, wherein the compensation counter module includes:
N compensation counters, the N compensation counters include the first compensation counter, and a kth compensation counter in the N compensation counters is used to calculate a clock cycle of a kth compensation number corresponding to the reference clock and output a kth compensation clock, where the kth compensation number is greater than a k−1th compensation number, the compensation signal further includes the kth compensation clock, N is an integer greater than or equal to 2, and k is an integer of any of 2 to N.

11. The controller according to claim 10, wherein the clock generator uses the first compensation clock to the Nth compensation clock that are included in the compensation signal and when any compensation clock is in a second state, the corresponding pulse in the clock trigger signal is canceled according to the compensation signal to generate the target clock signal.

12. The controller according to claim 9, wherein the interface protocol is a Universal Flash Storage (UFS) standard.

13. A storage device capable of linking to a host according to an interface protocol, the storage device including:
an interface circuit for implementing a physical layer of the interface protocol to link with the host; and
a device controller for coupling to the interface circuit and a storage module, wherein the device controller includes:
a processing unit; and
a clock generating device, which is coupled to the processing unit and includes:
a clock generator counter for outputting a clock trigger signal according to a clock period of each reference number of a reference clock;
a compensation counter module for outputting a compensation signal, the compensation counter module includes:
a first compensation counter for outputting a first compensation clock according to a clock period of each first compensation number of the reference clock, wherein the first compensation number is greater than the reference number, and the compensation signal includes the first compensation number of the first compensation clock; and
a clock generator for receiving the clock trigger signal and the compensation signal to generate a target clock signal, where
the clock generator generates the target clock signal according to the clock trigger signal when the compensation signal is in a first state;
when the compensation signal is in a second state, the clock generator cancels a corresponding pulse in the clock trigger signal according to the compensation signal to generate the target clock signal;
when the processing unit activates the clock generating device, the processing unit transmits a value of the reference number to the clock generator counter and at least transmits a value of the first compensation number to the first compensation counter.

14. The storage device according to claim 13, wherein the interface protocol is a Universal Flash Storage (UFS) standard.
